(19) United States
(12) Patent Application Publication
(10) Pub. No.: US 2020/0075560 A1
(43) Pub. Date: Mar. 5, 2020

(54) METHOD FOR TRANSFERRING MICRO-LIGHT EMITTING DIODES, MICRO-LIGHT EMITTING DIODE DEVICE AND ELECTRONIC DEVICE

(71) Applicant: GOERTEK INC., Weifang City, Shandong Province (CN)

(72) Inventors: Quanbo ZOU, Weifang City, Shandong Province (CN); Peixuan CHEN, Weifang City, Shandong Province (CN)

(73) Assignee: GOERTEK INC., Weifang City, Shandong Province (CN)

(21) Appl. No.: 16/609,269

(22) PCT Filed: Jun. 15, 2017
(86) PCT No.: PCT/CN2017/088381

§ 371 Date: Oct. 29, 2019

(51) Int. Cl. H01L 25/075; H01L 33/62; H01L 33/00

(52) U.S. Cl. CPC H01L 25/0753; H01L 2933/0066; H01L 33/0079; H01L 33/62

(57) ABSTRACT

A method for transferring micro-light emitting diodes, a micro-light emitting diode device and an electronic device. The method for transferring micro-light emitting diodes comprises: providing bumps of bonding agent on electrode bonding pads of a receiving substrate and/or on micro-light emitting diodes of an original substrate; aligning and contacting the electrode bonding pads of the receiving substrate and the micro-light emitting diodes of the original substrate, to position the bumps of bonding agent between the micro-light emitting diodes and the electrode bonding pads; irradiating locally by using a first laser from the original substrate side, to melt the bumps of bonding agent to bond the micro-light emitting diodes and the electrode bonding pads; and stripping off the micro-light emitting diodes from the original substrate, to transfer the micro-light emitting diodes to the receiving substrate.

### TECHNICAL FIELD

The present disclosure relates to the technical field of micro-light emitting diodes, and particularly to a method for transferring micro-light emitting diodes, a micro-light emitting diode device and an electronic device.

### BACKGROUND ART

Micro-light emitting diodes (MicroLED) technique refers to the fabrication of MicroLED devices by integrating a LED array of high density and small sizes on a growth substrate, to realize the filming, microminiaturization and matrixing of the MicroLED Devices. The distance between neighbor pixels in micro-light emitting diode arrays is at micrometer level, and the realized LED devices have small volume, low power consumption and high brightness, and have super high resolutions and color saturations. Moreover, the micro-light emitting diode arrays have high response speed and long service life.

In the fabricating and using of micro-light emitting diodes, micro-light emitting diodes must be fabricated and generated on a growth substrate, and cannot be directly formed on the receiving substrate on which the micro-light emitting diodes are intended to be provided. Therefore, the transferring of the micro-light emitting diodes from the growth substrate (that is, the original substrate) to a receiving substrate is required. The receiving substrate is for example a display screen. In the process of the transferring, bonding between the micro-light emitting diodes and the receiving substrate is required.

However, in the prior art for transferring micro-light emitting diode arrays that has been disclosed so far (shown by FIG. 1), the original substrate 1 and the receiving substrate 2 are required to be heated to a high temperature (approximately 200° C.), to realize the bonding of the micro-light emitting diodes 3 and the receiving substrate 2. Due to the high temperature for bonding, mismatch of the original substrate 1 and the receiving substrate 2 is caused by thermal expansion, which reduces the product quality. Especially when the requirement on the resolution is high or when the array to be transferred is large, the product quality is affected more seriously.

### SUMMARY OF THE DISCLOSURE

In order to improve the prior art and solve the problems of the prior art, a major object of the present disclosure is to provide a method for transferring micro-light emitting diodes, a micro-light emitting diode device and an electronic device.

In order to achieve the above object, different embodiments individually teach the following multiple technical solutions:

According to an aspect of the present disclosure, there is provided a method for transferring micro-light emitting diodes, wherein, the method comprises the steps of:

providing bumps of bonding agent on electrode bonding pads of a receiving substrate and/or on micro-light emitting diodes of an original substrate;

aligning and contacting the electrode bonding pads of the receiving substrate and the micro-light emitting diodes of the original substrate, to position the bumps of bonding agent between the micro-light emitting diodes and the electrode bonding pads;

irradiating locally by using a first laser from the original substrate side, to melt the bumps of bonding agent to bond the micro-light emitting diodes and the electrode bonding pads; and
stripping off the micro-light emitting diodes from the original substrate, to transfer the micro-light emitting diodes to the receiving substrate.

Optionally, the bumps of bonding agent are solders or electrically conductive adhesives.

Optionally, a force is applied simultaneously with the irradiating locally by the first laser, to pack the original substrate and the receiving substrate together.

Optionally, a diameter of a light beam of the first laser is 1-100 micrometers, and a wavelength is 300-6000 nanometers.

Optionally, in the steps of melt-bonding and stripping, the receiving substrate and the original substrate are maintained at room temperature.

Optionally, the original substrate is a sapphire substrate.

Optionally, the step of stripping off the micro-light emitting diodes from the original substrate comprises:

irradiating locally by using a second laser from the original substrate side, and stripping the bonded micro-light emitting diodes off the original substrate, wherein the wavelength of the second laser is less than the wavelength of the first laser.

Optionally, the method further comprises the following step of:

repeatedly executing the method for transferring micro-light emitting diodes, to transfer the micro-light emitting diodes on multiple original substrates that have micro-light emitting diodes of different colors to the same receiving substrate, to realize color-by-color transferring of the micro-light emitting diodes of multiple colors.

Optionally, the micro-light emitting diodes on the multiple original substrates that have the micro-light emitting diodes of the different colors are transferred alternatively to a plurality of receiving substrates.

According to another aspect of the present disclosure, there is provided a micro-light emitting diode device, comprising a receiving substrate which is provided with micro-light emitting diodes, wherein the micro-light emitting diodes on the receiving substrate are transferred by using the method for transferring micro-light emitting diodes as stated above.

According to still another aspect of the present disclosure, there is provided an electronic device, wherein the electronic device comprises the micro-light emitting diode device as stated above.

The present disclosure of welding, by heating quickly and locally by laser irradiation, the micro-light emitting diodes and the receiving substrate, avoids the overall warming-up of the receiving substrate and the original substrate, reduces the heat mismatch phenomenon, and optimizes the process of bonding of the micro-light emitting diodes. In addition, the laser irradiation bonding can be easily controlled by programs, and can selectively bond the required micro-light emitting diode array. Control of the transferring process is eased and facilitated

### BRIEF DESCRIPTION OF THE DRAWINGS

FIG. 1 is the schematic diagram of the principle of the bonding of the micro-light emitting diode transferring of the prior art;

FIG. 2 is the schematic diagram of the flow of the method for transferring micro-light emitting diodes that is provided by an embodiment of the present disclosure;

FIG. 3 is the schematic diagram of the principle of the bonding of the method for transferring micro-light emitting diodes that is provided by an embodiment of the present disclosure;

FIGS. 4a-4e schematically show the procedure of the method for transferring micro-light emitting diodes that is provided by an embodiment of the present disclosure; and

FIGS. 5a-5d schematically show the procedure of the method for transferring micro-light emitting diodes that is provided by another embodiment of the present disclosure.

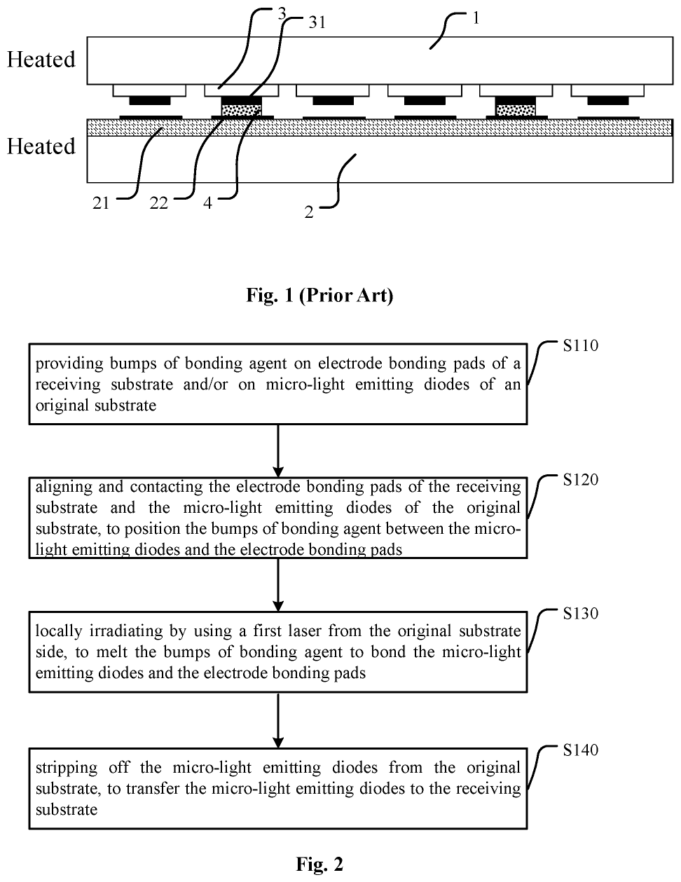

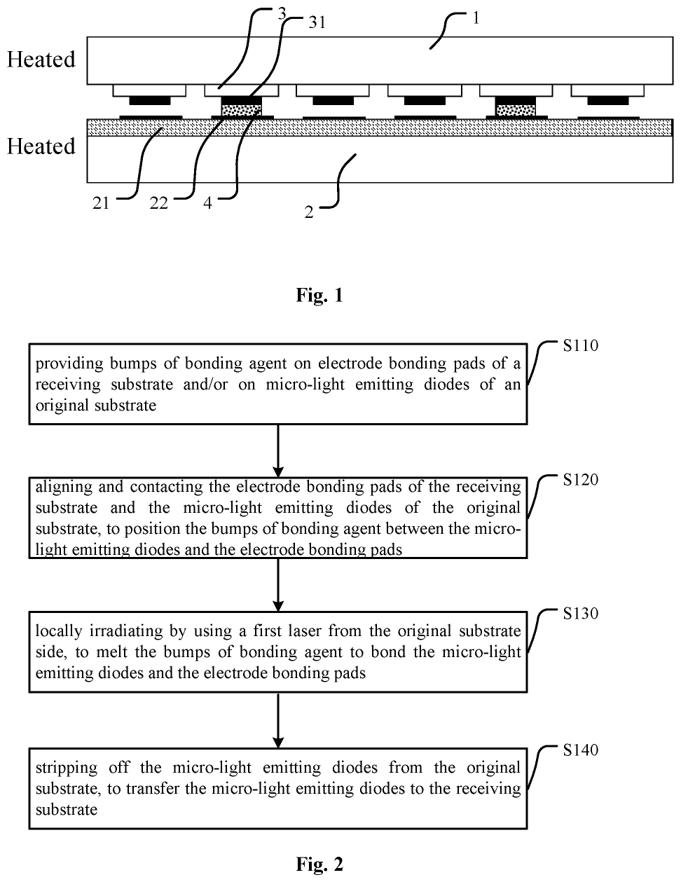

In the drawings, 1 denotes the original substrate; 2 the receiving substrate; 21 the thin film transistor layer; 22 the electrode bonding pads; 3 the micro-light emitting diodes; 31 the P electrodes; 4 the bumps of bonding agent; 5 the first laser; and 6 the second laser.

### DETAILED DESCRIPTION

In order to make the objects, the technical solutions and the advantages of the present disclosure clearer, the embodiments of the present disclosure will be described below in further detail in conjunction with the drawings.

FIG. 2 schematically shows an embodiment of the method for transferring micro-light emitting diodes of the present disclosure. As shown by FIG. 2, the method comprises the steps of:

Step S110, providing bumps of bonding agent on electrode bonding pads of a receiving substrate and/or on micro-light emitting diodes of an original substrate. Usually a bump of bonding agent is provided on each electrode bonding pad for receiving or a bump of bonding agent is provided on each micro-light emitting diode to be transferred.

Step 5120, aligning and contacting the electrode bonding pads of the receiving substrate and the micro-light emitting diodes of the original substrate, to position the bumps of bonding agent between the micro-light emitting diodes and the electrode bonding pads.

Step 5130, irradiating locally by using a first laser from the original substrate side, to melt the bumps of bonding agent and bond the micro-light emitting diodes and the electrode bonding pads.

Step 5140, stripping off the micro-light emitting diodes from the original substrate, to transfer the micro-light emitting diodes to the receiving substrate.

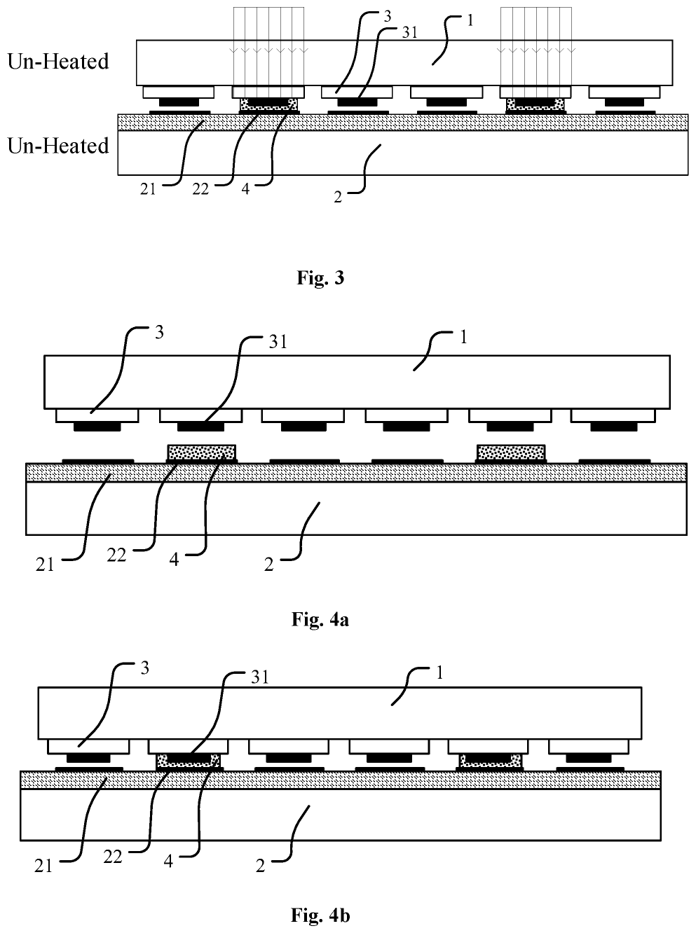

The present disclosure is different from the prior art, in that it does not employ the bonding manners that require the overall heating of the original substrate and the receiving substrate such as reflow soldering. The present disclosure realizes the quick local heating of the bonding agent by providing the bumps of bonding agent and by using the first laser to irradiate the bonding agent. By the laser irradiating, the bumps of bonding agent are molten so as to weld the micro-light emitting diodes and the receiving substrate together, which can particularly be seen in FIG. 3. The present disclosure, by using the laser irradiating to realize local heating, avoids the overall warming-up of the receiving substrate and the original substrate, reduces the defects of thermal expansion mismatch, and optimizes the bonding of the micro-light emitting diodes. In addition, the laser irradiation can be easily controlled by programs, and can selectively bond the required micro-light emitting diode array. Control of the transferring process is eased and facilitated.

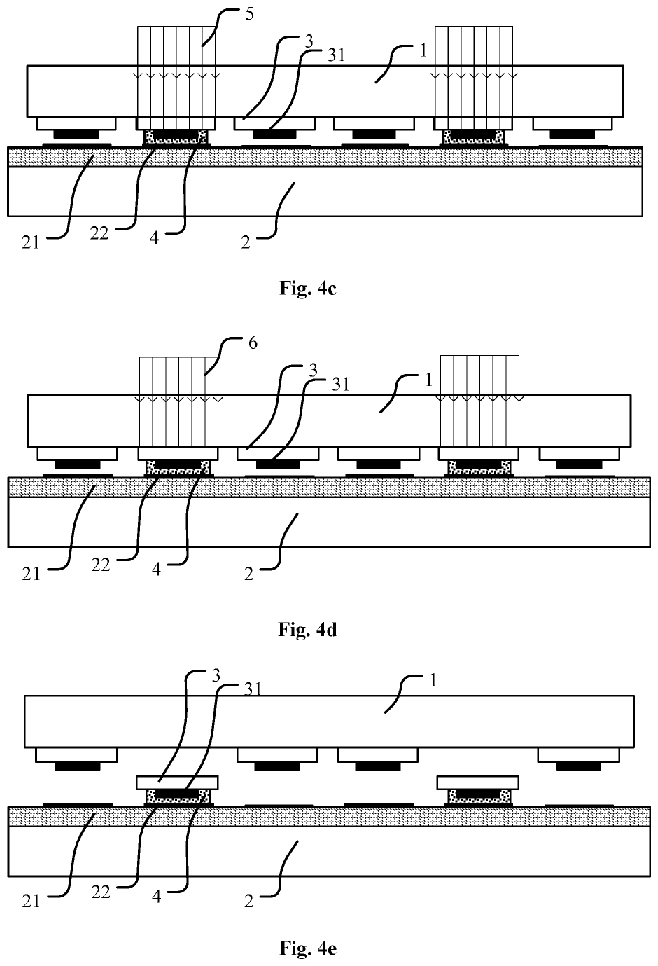

By referring to the process flow diagrams shown by FIGS. 4a-4e below, a special embodiment of the method for transferring micro-light emitting diodes of the present disclosure is introduced.

As shown by FIG. 4a, an original substrate 1 serves as the growth substrate of micro-light emitting diodes 3, and the growth substrate, such as a sapphire substrate, is transparent to lasers. The micro-light emitting diodes 3 are grown on the growth substrate, and the base layers (such as gallium nitride) of the micro-light emitting diodes 3 are provided with P electrodes 31. In the present embodiment, the P electrodes 31 are facing the receiving substrate 2. The receiving substrate 2 is a display panel, and is provided with a thin film transistor layer 21. Electrode bonding pads 22 are provided on the top of the thin film transistor layer 21. As shown by FIG. 4a, in the transferring method of the present disclosure, bumps of bonding agent 4 are firstly provided on the electrode bonding pads 22 of the receiving substrate 2, wherein the bumps of bonding agent 4 may be provided by one or more of the ways of etching, depositing, photo etching and electroplating. Certainly, the bumps of bonding agent 4 may also be provided on the P electrodes 31 of the micro-light emitting diodes of the original substrate 1, or provided on both of the electrode bonding pads 22 and the P electrodes 31 of the micro-light emitting diodes. In the present embodiment, the bumps of bonding agent 4 are provided on the receiving substrate 2. Generally, the size of the original substrate 1 is less than the size of the receiving substrate 2, so the original substrate 1 is provided over the receiving substrate 2.

Preferably, the bumps of bonding agent 4 may be solders, such as, but not limited to, tin solder. Alternatively, the bumps of bonding agent 4 may also be electrically conductive adhesives, such as, but not limited to, conductive silver paste. Both of the solder and the electrically conductive adhesives may be molten by the irradiation by a first laser, so as to bond the P electrodes 31 of the micro-light emitting diodes 3 and the electrode bonding pads 22 of the receiving substrate 2 together.

As shown by FIG. 4b, the original substrate 1 and the receiving substrate 2 are aligned and packed together, to enable the P electrodes 31 of the micro-light emitting diodes and the electrode bonding pads 22 of the receiving substrate 2 to align, and to contact via the bumps of bonding agent 4.

As shown by FIG. 4c, locally heating the locations of the micro-light emitting diodes 3 that are intended to be transferred, by irradiating using the first laser 5 from the original substrate side 1, which is transparent to lasers. The bumps of bonding agent 4 contains a metal, and the metal is warmed and molten after absorbing the energy of the first laser 5, so as to bond the P electrodes 31 of the micro-light emitting diodes 3 and the electrode bonding pads 22 of the receiving substrate 2 together.

In that, the diameter of the light beam of the employed first laser 5 is 1-100 micrometers, and the wavelength is 300-6000 nanometers. Because the bumps of bonding agent 4 have very small volumes, the warming-up does not require too much heat, and the irradiation duration of the first laser 5 may be in the range of microseconds to milliseconds. In the embodiments of the present disclosure, because the heat quantity is small, the heat elimination is fast, and the molten bumps of bonding agent 4 can be cooled and solidified very quickly, to realize a firm bonding. By the irradiation using the first laser 5, the bumps of bonding agent 4 are accurately heated, which avoids the overall warming-up of the original substrate 1 and the receiving substrate 2, and reduces the thermal expansion mismatch phenomenon that is caused by the warming-up of them.

In a preferable embodiment, in order to ensure the reliability and firmness of the bonding, a force may also be applied simultaneously with the irradiating locally using the first laser 5. For example, the original substrate 1 may be pressed or the original substrate 1 and the receiving substrate 2 may be clamped by a jig, to pack the original substrate 1 and the receiving substrate 2 together. That may further ensure the firm bonding between the molten bumps of bonding agent 4 and the P electrodes 31 of the micro-light emitting diodes 3 and the electrode bonding pads 22 of the receiving substrate 2.

In another preferable embodiment, in the process of providing the bumps of bonding agent that is shown by FIG. 4a and the flow of melt-bonding that is shown by FIG. 4c, both of the receiving substrate 2 and the original substrate 1 are maintained at room temperature, for example, maintained at 20-30° C. Because the bonding is conducted at room temperature, the fabrication temperature of the receiving substrate 2 (display panel) is the same as its working temperature, and no new defects will be introduced by the bonding.

As shown by FIG. 4d, in the embodiments of the present disclosure, the step of stripping off the micro-light emitting diodes from the original substrate comprises:

Irradiating locally from the original substrate side 1, which is transparent to laser, using a second laser 6, to strip off the bonded micro-light emitting diodes 3 from the original substrate 1 and transfer the bonded micro-light emitting diodes 3 to the receiving substrate 2. The wavelength of the selected second laser 6 is less than the wavelength of the first laser 5 and cannot penetrate the base layers (such as gallium nitride) of the micro-light emitting diodes 3. The second laser 6 is absorbed at the base layers (such as gallium nitride) of the micro-light emitting diodes 3, to separate the base layers and the original substrate 1, to realize the stripping and transferring of the micro-light emitting diodes 3. The wavelength of the second laser 6 may be set to be approximately 200 nanometers. The process of stripping off the micro-light emitting diodes 3 using the second laser 6 may also be conducted at room temperature. Furthermore, the stripping of the micro-light emitting diodes 3 may also be done by mechanic stripping or chemical stripping, which will not be described in further detail here.

Finally, as shown by FIG. 4e, the original substrate 1 is removed, to complete the transferring of the micro-light emitting diodes 3 from the original substrate 1 to the receiving substrate 2.

In another embodiment of the present disclosure, it is intended to transfer light emitting diodes of different colors to the same receiving substrate, to realize for example a display panel of colors or full color. Therefore, the method for transferring micro-light emitting diodes of the embodiment comprises: repeatedly executing the method for transferring micro-light emitting diodes that is described above, to transfer the micro-light emitting diodes on multiple original substrates that have micro-light emitting diodes of different colors to the same receiving substrate, to realize color-by-color transferring of the micro-light emitting diodes of multiple colors. Because in the current fabrication process of micro-light emitting diodes, only micro-light emitting diodes of one color can be fabricated on one growth substrate at one time, a display panel of full color (such as the three primary colors red, green and blue) can be fabricated by repeatedly executing the above steps by using multiple different original substrates to color-by-color transfer the micro-light emitting diodes to the same receiving substrate.

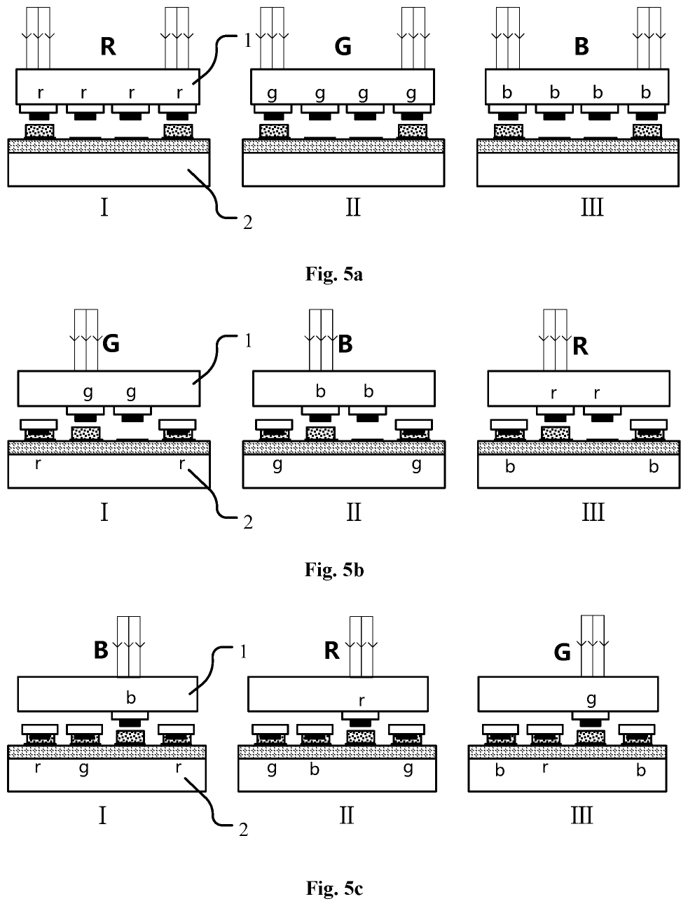

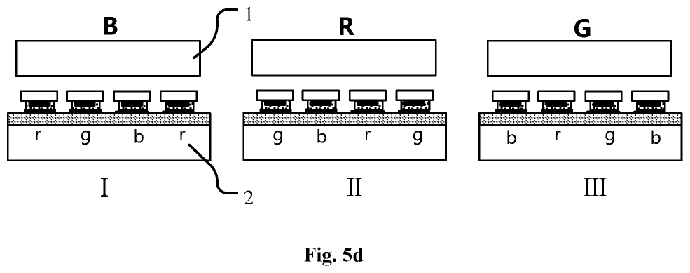

More preferably, in the process of the above repeatedly executing the transferring of the micro-light emitting diodes, a plurality of original substrates that have micro-light emitting diodes of different colors are simultaneously used, and the micro-light emitting diodes on them are transferred alternatively to a plurality of receiving substrates. That is particularly illustrated by referring to the embodiment shown by FIG. 5a to FIG. 5d below.

In the embodiment shown by FIG. 5a to FIG. 5d, original substrates (R, B) of micro-light emitting diodes of the three primary colors red, green and blue are concurrently and alternatively used, and the micro-light emitting diodes (r, g, b) of the three primary colors red, green and blue on them are transferred to receiving substrates (I, II, III). As shown by FIG. 5a, in the first transferring, the micro-light emitting diodes are transferred according to the corresponding relations of R-I, G-II and B-III. As shown by FIG. 5b, in the second transferring, the micro-light emitting diodes are transferred according to the corresponding relations of G-I, B-II and R-III. As shown by FIG. 5c, in the third transferring, the micro-light emitting diodes are transferred according to the corresponding relations of B-I, R-II and G-III.

By concurrently and alternatively transferring the micro-light emitting diodes, multiple different original substrates can be simultaneously used, which accelerates the process of transferring and fabricating. In addition, by alternatively using the different original substrates, interference between micro-light emitting diodes of different colors can be avoided automatically.

The present disclosure further discloses a micro-light emitting diode device comprising a receiving substrate. The receiving substrate is provided with micro-light emitting diodes and the micro-light emitting diodes on the receiving substrate is transferred by using the method for transferring micro-light emitting diodes as stated above. The micro-light emitting diode device may be a display panel, such as a LED display screen or a LCD display screen. Because the manufacturing process of the micro-light emitting diode device does not have the thermal expansion mismatch of the receiving substrate, it has more stable product quality and longer service life.

The present disclosure further discloses an electronic device, wherein the electronic device comprises the micro-light emitting diode device as stated above. The electronic device may be a mobile telephone, a television set or a tablet computer.

The above are only special embodiments of the present disclosure. By the teaching of the present disclosure, a person skilled in the art can make other modifications or variations on the basis of the above embodiments. A person skilled in the art should appreciate that, the above special descriptions are only for the purpose of better explaining the present disclosure, and the protection scope of the present disclosure should be subject to the protection scope of the claims.

1. A method for transferring micro-light emitting diodes, wherein, the method comprises the steps of:
providing bumps of bonding agent on electrode bonding pads of a receiving substrate and/or on micro-light emitting diodes of an original substrate;
aligning and contacting the electrode bonding pads of the receiving substrate and the micro-light emitting diodes of the original substrate, to position the bumps of bonding agent between the micro-light emitting diodes and the electrode bonding pads;
locally irradiating by using a first laser from the original substrate side, to melt the bumps of bonding agent to bond the micro-light emitting diodes and the electrode bonding pads; and
stripping off the micro-light emitting diodes from the original substrate, to transfer the micro-light emitting diodes to the receiving substrate.

2. The method for transferring micro-light emitting diodes according to claim 1, wherein, the bumps of bonding agent are solders or electrically conductive adhesives.

3. The method for transferring micro-light emitting diodes according to claim 1, wherein, a force is applied simultaneously with the irradiating locally using the first laser, to pack the original substrate and the receiving substrate together.

4. The method for transferring micro-light emitting diodes according to claim 1, wherein, the diameter of a light beam of the first laser is 1-100 micrometers and the wavelength is 300-6000 nanometers.

5. The method for transferring micro-light emitting diodes according to claim 1, wherein, in the steps of melt-bonding and stripping, the receiving substrate and the original substrate are maintained at room temperature.

6. The method for transferring micro-light emitting diodes according to claim 1, wherein, the original substrate is a sapphire substrate.

7. The method for transferring micro-light emitting diodes according to claim 1, wherein, the step of stripping off the micro-light emitting diodes from the original substrate comprises:
irradiating locally by using a second laser from the original substrate side, and stripping the bonded micro-light emitting diodes off the original substrate, wherein the wavelength of the second laser is less than the wavelength of the first laser and cannot penetrate the base layers of the micro-light diodes.

8. The method for transferring micro-light emitting diodes according to claim 7, wherein, the method further comprises the following step:
repeatedly executing the method for transferring micro-light emitting diodes, to transfer the micro-light emitting diodes on multiple original substrates that have micro-light emitting diodes of different colors to the same receiving substrate, to realize color-by-color transferring of the micro-light emitting diodes of multiple colors.

9. The method for transferring micro-light emitting diodes according to claim 7, repeatedly executing the method for transferring micro-light emitting diodes, the micro-light emitting diodes on the multiple original substrates that have the micro-light emitting diodes of the different colors are transferred alternatively to a plurality of receiving substrates.

10. A micro-light emitting diode device, comprising a receiving substrate, wherein the receiving substrate is provided with micro-light emitting diodes, the micro-light emitting diodes on the receiving substrate are transferred by using a method for transferring micro-light emitting diodes as following:
providing bumps of bonding agent on electrode bonding pads of a receiving substrate and/or micro-light emitting diodes of the original substrate;
aligning and contacting the electrode bonding pads of the receiving substrate and the micro-light emitting diodes of the original substrate, to position the bumps of bonding agent between the micro-light emitting diodes and the electrode bonding pads;
locally irradiating by using a first laser from the original substrate side, to melt the bumps of bonding agent to bond the micro-light emitting diodes and the electrode bonding pads; and
stripping off the micro-light emitting diodes from the original substrate, to transfer the micro-light emitting diodes to the receiving substrate.

11. An electronic device, wherein, the electronic device comprises the micro-light emitting diode device according to claim 10.

12. The micro-light emitting diode device according to claim 10, wherein, the bumps of bonding agent are solders or electrically conductive adhesives.

13. The micro-light emitting diode device according to claim 10, wherein, a force is applied simultaneously with the irradiating locally using the first laser, to pack the original substrate and the receiving substrate together.

14. The micro-light emitting diode device according to claim 10, wherein, the diameter of a light beam of the first laser is 1-100 micrometers and the wavelength is 300-6000 nanometers.

15. The micro-light emitting diode device according to claim 10, wherein, in the steps of melt-bonding and stripping, the receiving substrate and the original substrate are maintained at room temperature.

16. The micro-light emitting diode device according to claim 10, wherein, the original substrate is a sapphire substrate.

17. The micro-light emitting diode device according to claim 10, wherein, the step of stripping off the micro-light emitting diodes from the original substrate comprises:
irradiating locally by using a second laser from the original substrate side, and stripping the bonded micro-light emitting diodes off the original substrate, wherein the wavelength of the second laser is less than the wavelength of the first laser and cannot penetrate the base layers of the micro-light emitting diodes.

18. The micro-light emitting diode device according to claim 17, wherein, the method further comprises the following step:
repeatedly executing the method for transferring micro-light emitting diodes, to transfer the micro-light emitting diodes on multiple original substrates that have micro-light emitting diodes of different colors to the same receiving substrate, to realize color-by-color transferring of the micro-light emitting diodes of multiple colors.

19. The micro-light emitting diode device according to claim 17, wherein, repeatedly executing the method for transferring micro-light emitting diodes, the micro-light emitting diodes on the multiple original substrates that have the micro-light emitting diodes of the different colors are transferred alternatively to a plurality of receiving substrates.
